(19) United States
(12) Patent Application Publication
(10) Pub. No.: US 2021/0233731 A1
(43) Pub. Date: Jul. 29, 2021

(54) HYBRID AMPLIFIER FOR INDUCTIVE LOAD

(71) Applicant: Freemelt AB, Mölndal (SE)

(72) Inventors: Robin STEPHANSEN, Mölndal (SE); Fredrik SELMOSSON, Kållered (SE)

(73) Assignee: Freemelt AB, Mölndal (SE)

(21) Appl. No.: 17/053,447

(22) PCT Filed: May 9, 2019
(86) PCT No.: PCT/EP2019/061918

§ 371 Date: Nov. 6, 2020

Related U.S. Application Data
(60) Provisional application No. 62/668,864, filed on May 9, 2018.

(51) Int. Cl. H01J 29/70; H03F 3/04

(52) U.S. Cl. CPC H01J 29/70; H01J 2229/581; H03F 3/04

(57) ABSTRACT

The present invention relates to a circuit arrangement comprising an analogue amplifier electrically connected to a first end of an inductive load. Further at least one electrical switch is electrically connected to a second end of the inductive load, where the electrical switch increases the rate of current change in the inductive load by applying an electrical voltage potential to the second end of the inductive load. The voltage at the second end can also be switched by a digital circuit at the second end for improved performance The inductive load may e.g. be a beam control coil, which may be provided for controlling an electron beam, e.g. in an electron gun.

### TECHNICAL FIELD

Electronic amplifiers are used in many different applications. This invention relates to a circuit arrangement with an amplifier driving a current through an inductive load and a switch connected to the opposite end of the inductive load. One application for such an arrangement is a circuit arrangement where the inductive load is a coil for controlling a charged particle beam, e.g. in an electron gun.

### DESCRIPTION OF RELATED ART

An inductive load such as a coil has a high impedance with respect to high frequencies and a lower impedance with respect to low frequencies, i.e. the load requires a large voltage to rapidly change the current through the coil but only requires a low voltage to maintain the current through the coil. When an analogue amplifier is used to drive the current through an inductive load in a context where large rapid changes of the current through the inductive load are required, the analogue amplifier needs to be able to handle both a high supply voltage and a high power. Typically, when driving analogue amplifiers, a high power leads to substantial heat generation which in turn leads to a trade-off between on one hand the ability to withstand this power and on the other hand a rapid response from the amplifier. Thus, there is normally a choice between bandwidth and power when selecting an amplifier for driving an inductive load.

### SUMMARY OF THE INVENTION

This invention relates to a circuit arrangement comprising an analogue amplifier connected to a first end of an inductive load, and at least one electrical switch connected to a second end of said inductive load, where the at least one electrical switch increases the rate of current change in the inductive load by applying a voltage potential to the second end of the inductive load.

In embodiments, the analogue amplifier connected to the first end of the inductive load controls the static current through the inductive load.

In embodiments, the at least one electrical switch connected to a second end of the inductive load controls the rate of current change through the inductive load.

In embodiments, the second end of the inductive load is connected to a fixed voltage potential when the at least one electric switch is non-conducting.

In embodiments, the second end of the inductive load is connected to the fixed voltage potential through a resistor.

In embodiments, the second end of the inductive load is connected to the fixed voltage potential through a inductor.

In embodiments, the second end of the inductive load is connected to the fixed voltage potential through a capacitor.

In embodiments, the at least one electrical switch is activated when the control signal to the analogue amplifier connected to a first end of the inductive load is changed.

In embodiments, the at least one electrical switch is activated when the output signal from the analogue amplifier connected to a first end of the inductive load is changed.

In embodiments, the at least one electrical switch is activated when there is a measured difference between demanded current and actual current through the inductive load.

In embodiments, the at least one electrical switch is activated when there is a predicted current change through the inductive load.

In embodiments, the at least one electrical switch is deactivated when the current through the inductive load has reached a desired value.

In embodiments, the current through the inductive load is measured.

In embodiments, the current through the electrical switch is measured.

In embodiments, the inductive load is a coil.

In embodiments, the electrical switch is a voltage switch.

In embodiments, the inductive load is a beam control coil.

In embodiments, the beam control coil is provided for controlling an electron beam, e.g. in an electron gun. This enables fast movement of the electron beam, without demanding the amplifier at the first end to be designed for a higher voltage.

In embodiments, the at least one electrical switch is at least one transistor.

In embodiments, the at least one electrical switch is at least one thyristor.

In embodiments, the at least one electrical switch is at least one analogue amplifier.

In embodiments, at least one electrical switch is connected to a second end of the inductive load for controlling the voltage at the second end by repeatedly switching between at least two different voltage levels for controlling the rate of current change in the inductive load.

This invention further relates to an electron gun for generating an electron beam comprising a beam control coil for controlling the position and/or orientation of an electron beam, and a circuit arrangement. The circuit arrangement may comprise an analogue amplifier connected to a first end of the beam control coil, and at least one electrical switch connected to a second end of the beam control coil. The least one electrical switch may be configured to control the voltage at the second end of the beam control coil by repeatedly switching between at least two different voltage levels. This controls the rate of current change in the beam control coil, and may thereby achieve a rapid change in the position and/or orientation of the electron beam.

In embodiments, the at least one electrical switch is configured to increase the rate of current change in the beam control coil by applying a voltage potential to the second end of the beam control coil.

In embodiments, the at least one electrical switch is configured to be activated when the control signal to, or the output signal from, the analogue amplifier connected to the first end of the beam control coil is changed.

In embodiments, the at least one electrical switch is configured to be activated when there is a measured difference between demanded current and actual current through the beam control coil, and/or when there is a predicted current change through the beam control coil.

The scope of the invention is defined by the claims, which are incorporated into this section by reference. A more complete understanding of embodiments of the invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF DRAWINGS

In the description of the invention references is made to the following figures, in which:

FIG. 1 shows, in schematic diagram, an inductive load with an analogue amplifier connected to a first end and electrical switches and a resistance connected to a second end of the inductive load.

FIG. 2 shows, in schematic diagram, an inductive load with an analogue amplifier connected to a first end and a digital circuit connected to a second end of the inductive load.

FIG. 3 shows, in schematic diagram, an inductive load with an analogue amplifier connected to a first end and electrical switches for connection of the second end of the inductive load to ground, a voltage U6, or an amplifier.

FIG. 4 shows, in a graph, the rate of current change during a change of current through the inductive load from I₁ to I₂, where t is time.

FIG. 5 shows, in a graph, a step change of the voltage potential Uₐₘₚ applied from the analogue amplifier to the first end of the inductive load, where t is time.

FIG. 6 shows, in a graph, a pulse change of the voltage potential U_{switch} applied from the electrical switch to the second end of the inductive load, where t is time.

FIG. 7 shows, in a graph, the voltage Uₜₒₜ=Uₐₘₚ−U_{switch} from the two voltage potentials in FIGS. 5 and 6, where t is time.

### DESCRIPTION AND DISCLOSURE OF THE INVENTION

The purpose of this invention is to provide a circuit arrangement, where an analogue amplifier is connected to a first end of an inductive load with enhanced performance upon rapid changes of current and voltage at the load, by providing e.g. a switch, a transistor, a thyristor, a digital circuit or an analogue amplifier at the second end of the load for controlling the electrical voltage at the second end of the load.

The inductive load may e.g. be a beam control coil, which may be used for controlling an electron beam, e.g. a charged particle beam in an electron gun. Electron guns are used in various machines and applications, such as in additive manufacturing machines for generating an electron beam, which is used for melting and/or sintering of metal powder. Additive manufacturing systems are also called 3D-printing systems and can e.g. be based on electron beam powder bed fusion. Additive manufacturing and 3D-printing refer to the process of manufacturing objects from 3D model data by joining powder materials layer upon layer. Powder bed fusion means additive manufacturing or 3D-printing where objects are built up in a powder bed. Thin layers of powder are repeatedly spread by a powder distributor over a powder bed and fused by an electron beam to a predetermined geometry for each layer. Other applications where electron guns are used are electron beam welding machines, electron beam lithography systems and electron microscopes.

When controlling an electron beam with a beam control coil, it is desired to achieve a fast current change through the coil to achieve fast changes/movement of the electron beam. Fast change of the electron beam is directly connected to the performance of a 3D-printing system. An alternative solution would be to provide a continuous higher voltage at the second end of the inductive load, but this would demand the amplifier at the first end to be designed for a higher voltage, which is more expensive and challenging from a technological point.

The switch connected to the second end of the inductive load can be controlled by the system for an optimized melt or heating pattern. There is a correlation between the electron beam melting/heating pattern at the powder bed and the possibility to control the beam control coil.

There are two types of powder bed fusion systems: Laser powder bed fusion (LPBF), where the laser beam positioning is accomplished using mechanical movement of one or several mirrors, and Electron beam powder bed fusion (EPBF), where magnetic coils are used to accomplish beam positioning. In the current state of the art, the beam positioning is two to three orders of magnitude faster for EPBF than for LPBF due to the fact that beam positioning in EPBF is not limited in speed by movement of a mechanical part, but instead by the slew rate of the coils and the coil amplifiers. The faster movement of the beam for EPBF enables valuable features for 3D-printing with EPBF compared with LPBF. It is possible to maintain many melt spots simultaneously in EPBF by fast movement of the beam to different locations on the build area. Current state of the art is to maintain up several tens of melt spots by rapid movement of the electron beam between these melt spots.

With the invention described herein, it is envisioned that the speed of the beam positioning can be increased with an additional two to three orders of magnitude. This will enable new ways of material processing using EPBF.

When driving an inductive load, like a coil, the change of current is described by dI/dt=U/L. The rate of change in current is thus proportional to the supplied voltage U divided by the coil inductance L. Therefore, the faster the required change in current through an inductive load, the higher the voltage applied over the inductive load needs to be. A coil is often embodied by a metallic conductor with a low resistance resulting in a low voltage across the coil to maintain a constant current.

An analogue amplifier can be seen as a variable resistor between a supply voltage and an output load. For a given output voltage, the difference between the supply voltage and the output voltage will be applied over this “resistance” of the analogue amplifier, and the current flowing through the output load connected to the amplifier will also flow through this “resistance”. The heat dissipated in this internal “resistor” can be calculated from the equation P=I_{load}*(U_{supply}−Uₒᵤₜₚᵤₜ) where P is the generated heating power, I_{load} is the current through the output load, U_{supply} is the analogue amplifier's supply voltage and Uₒᵤₜₚᵤₜ is the voltage over the output load.

When the output current and the difference between supply voltage and output voltage both increase, more heat will be dissipated in the analogue amplifier. To manage this heat dissipation, the design of the amplifier is usually a trade-off between dissipated heat and bandwidth, where bandwidth relates to the rate at which the amplifier can react to small changes in the input signal.

When an analogue amplifier changes the current through a inductive load in the described way, being restricted by a maximum voltage, it is able to supply across the output load, and its slew rate is determined by the load inductance and by the limited voltage that the amplifier can supply at its output. This current slew rate is the highest current change rate (dI/dt) the amplifier can achieve when connected to the inductive load. For a given load, the increasing of the slew rate requires an increase in the maximum output voltage of the amplifier. This leads to a trade-off between on one hand high bandwidth for rapid sequential small changes in current, and on the other hand slew rate for rapid larger current steps.

In this invention, a high bandwidth low voltage analogue amplifier may be combined with a high voltage digital circuit, where both are connected to the same inductive load. The low voltage amplifier may be connected to a first end of the inductive load, and the high voltage digital circuit may be connected to a second end of the inductive load. The analogue amplifier may be supplied with a voltage high enough to supply the required current in steady state, in which the coil acts as a resistor, and during small but rapid changes in the current, in which the coil acts as an inductive load. The low voltage analogue amplifier will thus be able to achieve a high bandwidth although the low supply voltage results in low current slew rate. The low voltage analogue amplifier will thus not perform well during larger steps in output current, but will excel during consecutive rapid small changes in output current. The digital circuit helps the analogue amplifier by digitally supplying a voltage potential to the second end of the inductive load during a short time when the current slew-rate is limited by the analogue amplifier's supply voltage, thus increasing the slew-rate for such larger steps.

The digital circuit does not necessarily have the precision to accurately regulate the output current to a desired value, but it is well suited to handle a high voltage, thus generating a fast current change, dI/dt.

As the digital circuit only conducts current when fully open, i.e. with a low resistance, very little heat is dissipated in the digital circuit even for the case when both its supply voltage and the load current is high. In this invention this may be achieved by connecting the analogue and digital control circuit at each end of the inductive load. The analogue amplifier may be designed as a high bandwidth current source supplied with a given voltage value. The digital circuit may be designed to connect the inductive load either to ground or to a selected voltage value. In this design, the analogue amplifier is thus a current source and it will therefore not react to the potential at the other end of the inductive load. The digital circuit preferably disconnects the inductive load from the selected voltage value as soon as the step change in current is complete, in order not to disrupt or damage the analogue amplifier.

One way of controlling the digital circuit is to use a separate circuit for monitoring the analogue amplifier output voltage and switching the digital circuit when the analogue amplifier output voltage is higher than a predetermined value. Another way of controlling the digital circuit is to use a separate circuit for monitoring an internal error signal from the analogue amplifier and switching the digital circuit when the error is greater than a predetermined value, where the error is the difference between desired output current and actual output current. In yet another way of controlling the digital circuit a digital processor uses a digital to analogue converter to control the output of the analogue amplifier and a digital output to control the digital circuit. Such a digital processor could activate the digital circuit ahead of the required switching of the digital circuit, if information about a large current step is known in advance and when the current change step is imminent, thus activating the digital circuit for an amount of time predicted from the size of the current step and from the current slew-rate that the digital circuit is able to achieve.

The analogue amplifier connected to the first end of the inductive load is provided for controlling the static current through the inductive load, and the electrical switch connected to the second end of the inductive load is provided for controlling the current change through the inductive load.

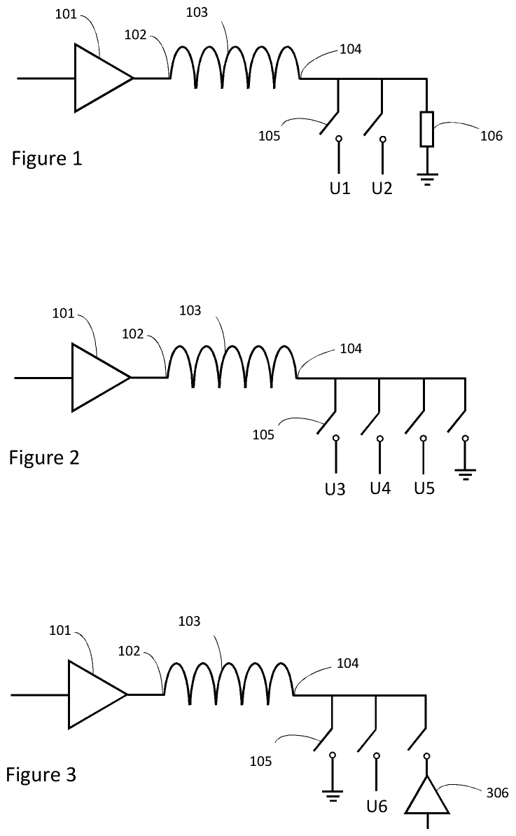

The second end of the inductive load can be connected to a fixed voltage potential when the electric switch at the second end is non-conducting for controlling the current through the inductive load. Alternatively, the second end of the inductive load can be connected to a fixed voltage potential through a resistor 106 as shown in FIG. 1 when the electric switches 105 are non-conducting.

To control and increase the rate of current change in the inductive load, the electrical switch can be activated when the input control signal to the analogue amplifier at the first end of the inductive load is changed. Alternatively, the electrical switch can be activated when the output signal from the analogue amplifier at the first end of the inductive load is changed. Alternatively, the electrical switch can be activated when there is a measured difference between demanded current and actual current through the inductive load. Alternatively, the electrical switch can be activated when there is a predicted imminent current change through the inductive load.

To enable the return of a stable current through the inductive load after a rapid change of the current, the electrical switch can be deactivated, i.e. non-conducting, when the current through the inductive load has reached a desired value.

The measured current through the inductive load or the measured current through the electrical switch can be used as feedback for controlling the circuit arrangement for improved or increased rate of current change in the inductive load.

A fast electrical switch connected to the second end of the inductive load can be used for controlling the average voltage at the second end by repeatedly switching between at least two different voltage levels for controlling the rate of current change in the inductive load. In this way, stepless control dI/dt (rate of current change) is possible.

The object of this invention is to achieve a circuit design for improved performance, when using a coil for controlling a charged particle beam being for instance an electron beam or an ion beam. This is achieved by the circuit arrangement defined in the independent claim. The dependent claims contain advantageous embodiments, variants and further developments of the invention.

In an embodiment of this invention, shown in FIG. 2, an analogue amplifier 101 is connected to a first end 102 of an inductive load 103. A digital circuit is connected to the second end of the inductive load 103 for controlling the voltage potential at the second end 104 of the inductive load 103. The digital circuit may have several electrical switches 105. The digital circuit at the second end is used to apply a large voltage selected by the individual electrical switches 105 to the inductive load 103, and the analogue amplifier 101 is used to apply smaller, more accurate voltages. The combination of all voltages determines the current through the inductive load. In a case with two switches, a first electrical voltage switch is connected to the second end 104 of the inductive load for applying a first voltage to the second end 104 of the inductive load 103, and a second electrical switch is connected to the second end 104 of the inductive load 103 for applying a second voltage to the second end 104 of the inductive load 103. In an embodiment, the inductive load 103 is a coil, more specific a beam control coil used for controlling and positioning an electron beam in an electron gun. The digital circuit at the second end 104 may be designed with several electrical switches 105 for switching between different selectable voltages U3, U4, U5 and ground potential, for controlling the rate of current change in the inductive load 103. The number of electrical switches and their corresponding voltages in the digital circuit can be chosen and designed for improved performance of the inductive load 103 controlling the electron beam. Further, the voltage values U3, U4, U5 can be fixed or variably selective.

The analogue amplifier 101 may act as a current source continuously monitoring the current through the inductive load 103 by comparing it to a control signal. This enables generation of an error signal, i.e. a signal representing the difference between demanded load current and actual load current. This signal can be used for determining the output voltage of the analogue amplifier 101. The error signal can also be monitored by means of a separate digital circuit. When such digital circuit detects that the error signal has reached a certain activation threshold, it can activate either of the electrical switches 105 until the error signal reaches a certain deactivation threshold.

FIG. 1 shows another embodiment of the invention, where an analogue amplifier 101 is connected to the first end 102 of an inductive load 103. A digital circuit at the second end 104 of the inductive load 103 is designed with two or more electrical switches 105 for fast switching of the voltage potential at the second end 104 of the inductive load 103, to achieve a desired voltage over the inductive load 103 and a fixed resistance 106, to set the voltage potential at the second end 104 of the inductive load 103 to ground potential when all voltage switches 105 are open. The fixed resistance 106 can be replaced by an inductance, a capacitance or a combination thereof, to achieve a desired voltage over the inductive load 103.

A further embodiment is shown in FIG. 3, where the digital circuit at the second end 104 of the inductive load 103 is designed with electrical switches 105 for switching between ground potential, a voltage potential U6, and a variable voltage potential supplied by a digital amplifier 306. The first end 102 of the inductive load 103 in this embodiment is connected to an analogue amplifier 101.

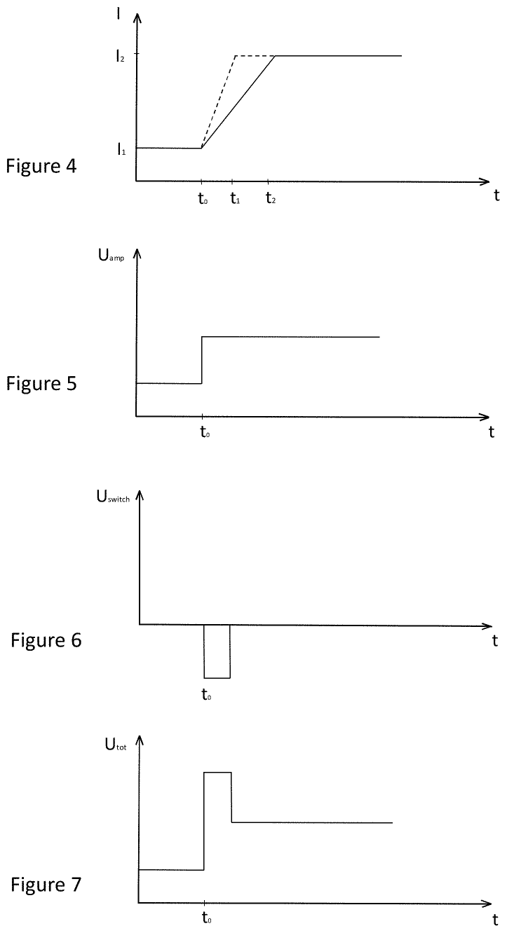

In FIG. 4 is shown the rate of current change through the inductive load. With an ordinary amplifier connected to the first end of a load, the change of current from I₁ to I₂ will need the time t₂−t₀. But with an electrical switch connected to the second end of the inductive load for applying a voltage potential to the second end of the inductive load, the time to change the current from I₁ to I₂ will be reduced to t₁−t₀, and hence the rate of current change will increase in accordance with this invention. This is illustrated with dashed lines in the graph in FIG. 4.

In FIGS. 5, 6 and 7 is shown how voltage may be applied over the inductive load to achieve the current change shown in graph 4 in accordance with this invention. The graph in FIG. 5 illustrates how the voltage potential Uₐₘₚ from the analogue amplifier may be increased at the first end of the inductive load at a time t₀ to achieve a change of current through the inductive load from I₁ to I₂. At the same time, t₀, as shown in FIG. 6, the electrical switch applies a voltage, U_{switch}, to the second end of the inductive load. The graph in FIG. 7 shows the total voltage, Uₜₒₜ=Uₐₘₚ−U_{switch}, of the two voltage potentials in FIGS. 5 and 6. When this voltage Uₜₒₜ is applied over the inductive load, the rate of current change will be increased in accordance with the dashed lines in the graph in FIG. 4.

The foregoing disclosure is not intended to limit the present invention to the precise forms or particular fields of use disclosed. It is contemplated that various alternate embodiments and/or modifications to the present invention, whether explicitly described or implied herein, are possible in light of the disclosure. Accordingly, the scope of the invention is defined only by the claims.

1. A circuit arrangement comprising an analogue amplifier connected to a first end of an inductive load, and at least one electrical switch connected to a second end of said inductive load, where the at least one electrical switch increases the rate of current change in the inductive load by applying a voltage potential to the second end of the inductive load.

2. The circuit arrangement according to claim 1, where the analogue amplifier connected to the first end of the inductive load controls the static current through the inductive load.

3. The circuit arrangement according to claim 1, where the at least one electrical switch connected to the second end of the inductive load controls the rate of current change through the inductive load.

4. The circuit arrangement according to claim 1, wherein the second end of the inductive load is connected to a fixed voltage potential when the at least one electric switch is non-conducting.

5. The circuit arrangement according to claim 4, wherein the second end of the inductive load is connected to the fixed voltage potential through a resistor, an inductor, and/or a capacitor.

6. The circuit arrangement according to claim 1, where said at least one electrical switch is activated when the control signal to, or the output signal from, the analogue amplifier connected to the first end of the inductive load is changed.

7. The circuit arrangement according to claim 1, where said at least one electrical switch is activated when there is a measured difference between demanded current and actual current through the inductive load, and/or when there is a predicted current change through the inductive load.

8. The circuit arrangement according to claim 1, wherein said at least one electrical switch is deactivated when the current through the inductive load has reached a desired value.

9. The circuit arrangement according to claim 1, wherein the current through the inductive load and/or the electrical switch is measured.

10. The circuit arrangement according to claim 1, wherein the inductive load is a coil.

11. The circuit arrangement according to claim 1, wherein the electrical switch is a voltage switch.

12. The circuit arrangement according to claim 1, wherein the inductive load is a beam control coil.

13. The circuit arrangement according to claim 12, wherein said beam control coil is provided for controlling an electron beam.

14. The circuit arrangement according to claim 1, wherein said at least one electrical switch is at least one transistor, is at least one thyristor, and/or at least one analogue amplifier.

15. The circuit arrangement according to claim 1, wherein at least one electrical switch is connected to a second end of said inductive load for controlling the voltage at said second end by repeatedly switching between at least two different voltage levels for controlling the rate of current change in said inductive load.

16. An electron gun for generating an electron beam comprising a beam control coil for controlling the position and/or orientation of an electron beam, and a circuit arrangement, wherein the circuit arrangement comprises an analogue amplifier connected to a first end of the beam control coil, and at least one electrical switch connected to a second end of the beam control coil, and wherein the least one electrical switch is configured to control the voltage at the second end of the beam control coil by repeatedly switching between at least two different voltage levels, in order to control the rate of current change in said beam control coil, and thereby achieve a rapid change in the position and/or orientation of the electron beam.

17. The electron gun according to claim 16, where the at least one electrical switch is configured to increase the rate of current change in the beam control coil by applying a voltage potential to the second end of the beam control coil.

18. The electron gun according to claim 16, where the at least one electrical switch is configured to be activated when the control signal to, or the output signal from, the analogue amplifier connected to the first end of the beam control coil is changed.

19. The electron gun according to claim 16, where the at least one electrical switch is configured to be activated when there is a measured difference between demanded current and actual current through the beam control coil, and/or when there is a predicted current change through the beam control coil.
